(19) United States
(12) Patent Application Publication
(10) Pub. No.: US 2001/0046744 A1
(43) Pub. Date: Nov. 29, 2001

(54) TRANSISTOR WITH REDUCED SERIES RESISTANCE JUNCTION REGIONS

(76) Inventors: BRIAN S. DOYLE, CUPERTINO, CA (US); DAVID B. FRASER, DANVILLE, CA (US)

Correspondence Address: MICHAEL A BERNADICOU, BLAKELY SOKOLOFF TAYLOR & ZAFMAN, 12400 WILSHIRE BOULEVARD, 7TH FLOOR, LOS ANGELES, CA, 90025

(21) Appl. No.: 09/229,592

(22) Filed: Jan. 13, 1999

(51) Int. Cl. H01L 21/336; H01L 21/4763; H01L 21/3205

(52) U.S. Cl. 438/305; 438/592

(57) ABSTRACT

An alignment component is formed on a substrate of a semiconductor material which is N- or P-doped. A metal layer is deposited over the substrate and the alignment component. The metal layer is reacted with the semiconductor material of the substrate to form two silicide regions, on opposing sides of the alignment component, which extend up to the alignment component. The alignment component is then replaced with a gate which extends up to the silicide regions. A transistor results wherein inner surfaces of the silicide regions, facing one another, are in direct contact with the N- or P-doped semiconductor material of the substrate and therefore have a low series resistance between them.

### BACKGROUND OF THE INVENTION

1). Field of the Invention

The present invention relates to a method of forming a metal-oxide-semiconductor (MOS) transistor, and to a MOS transistor.

2). Discussion of Related Art

Electronic circuits are often manufactured in and on semiconductor wafers such as silicon wafers. An electronic circuit of this kind consists of an integrated circuit of electronic components such as transistors, diodes, capacitors and other devices. One such a device which is very frequently used is a metal-oxide-semiconductor (MOS) transistor. In a MOS transistor a voltage is applied between source and drain regions and the transistor is “switched” by applying another voltage to a gate thereof. Ideally, a transistor should have a reaction time which is as fast as possible and a threshold voltage which is not exceedingly high. FIGS. 1a to 1e illustrate a conventional method of fabricating a conventional MOS transistor.

First, as illustrated in FIG. 1a, a gate 110 is formed on a P-doped substrate 112. N-doped source and drain regions 114 are then partially formed in the substrate 112 in an ion implantation process with the gate 110 providing alignment for purposes of forming the source and drain regions 114.

Non-conductive spacers 116 are then formed next to the gate 110, as illustrated in FIG. 1b. In another ion implantation process, the source and drain regions 114 are further formed with the spacers 116 providing alignment for purposes of forming the source and drain regions 114.

Next, as illustrated in FIG. 1c, a metal layer 118 is deposited over the gate 110, the spacers 116, and the source and drain regions 114.

The metal layer 118 is then heated. Heating of the metal layer 118 results in a reaction between the material of the source and drain regions 114 and the metal layer 118 so that highly conductive silicide regions 120 are formed on the source and drain regions 114, as illustrated in FIG. 1d. A portion of the metal layer 118 forms a metal strap between the silicide regions 120 and the gate 110. The metal strap is then etched away to finalize the fabrication of a MOS transistor 122 as illustrated in FIG. 1e.

The resulting transistor 122 has silicide regions 120 through which electrical connection to the source and drain regions 114 can be made. The source and drain regions 114 have tips 124 which are located between the silicide regions 120. The tips 124 result in a relatively high series resistance between the silicide regions 120. There is reason to believe that, by locating the silicide regions in direct contact with the P-doped material of the substrate 112 (also called Schottky junctions), a transistor can be provided wherein series resistance between the silicide regions is reduced and the reaction time of the transistor is increased.

Furthermore, in order to decrease the reaction time of the transistor 122, it may be necessary to reduce a gate length 126 of the transistor. There is, however, a risk of outdiffusion of dopants from the source and drain regions 114. A reduction in the gate length 126 of the transistor may, due to outdiffusion of dopants, result in leaking of the transistor 122. The risk of outdiffusion may be reduced by increasing the dopant concentration in the substrate 112. An increase in the dopant concentration of the substrate 112 may, however, result in a higher threshold voltage of the transistor 122. A Schottky junction type transistor and its fabrication are described in the specification of U.S. Pat. No. 4,485,550 to Koeneke. Although the transistor in the '550 patent does hold some distinct advantages over conventional MOS transistors, it does suffer from certain disadvantages, in particular that it has a gate dielectric layer which is very thick. The gate dielectric layer also separates silicide regions from a gate electrode by a distance which substantially reduces performance of the transistor, thus necessitating the need for doped source and drain regions.

### SUMMARY OF THE INVENTION

A method of forming a transistor is provided. An alignment component is formed on a substrate of a semiconductor material. A metal layer is deposited over the substrate and the alignment component. The metal layer is reacted with the semiconductor material of the substrate to form two silicide regions on opposing sides of the alignment component. The silicide regions substantially extend up to the alignment component. The alignment component is then replaced with a gate which substantially extends up to the silicide regions.

### BRIEF DESCRIPTION OF THE DRAWINGS

The invention is further described by way of example with reference to the accompanying drawings wherein:

FIG. 1a is a side view illustrating a substrate with a transistor gate formed thereon and source and drain regions which are partially formed after a first ion implantation step;

FIG. 1b is a view similar to FIG. 1a after spacers are formed next to the gate, and the source and drain regions are further formed in another ion implantation step;

FIG. 1c is a view similar to FIG. 1b after a metal layer is deposited;

FIG. 1d is a view similar to FIG. 1c after the metal layer is reacted with the substrate;

FIG. 1e is a view similar to FIG. 1d after a conventional MOS transistor is finally formed;

FIG. 2a is a side view of a substrate with an alignment component formed thereon;

FIG. 2b is a view similar to FIG. 2a after a metal layer is deposited;

FIG. 2c is a view similar to FIG. 2b after the metal layer is reacted with the substance to form silicide regions extending up to the alignment component.

FIG. 2d is a view similar to FIG. 2c after an unreacted portion of the metal layer is removed;

FIG. 2e is a view similar to FIG. 2d after a layer is deposited;

FIG. 2f is a view similar to FIG. 2e after the layer is planarized to expose the alignment component;

FIG. 2g is a view similar to FIG. 2f after the alignment component is removed to leave an opening;

FIG. 2h is a view similar to FIG. 2g after a gate dielectric layer is deposited;

FIG. 2i is a view similar to FIG. 2h after a metal layer is deposited;

FIG. 2j is a view similar to FIG. 2i after the metal layer and the gate dielectric layer are planarized;

FIG. 2k is a view similar to FIG. 2j after the layer is removed;

FIG. 3a is a view similar to FIG. 2a after a dopant implantation step; and

FIG. 3b is a view similar to FIG. 2k with additional, doped regions.

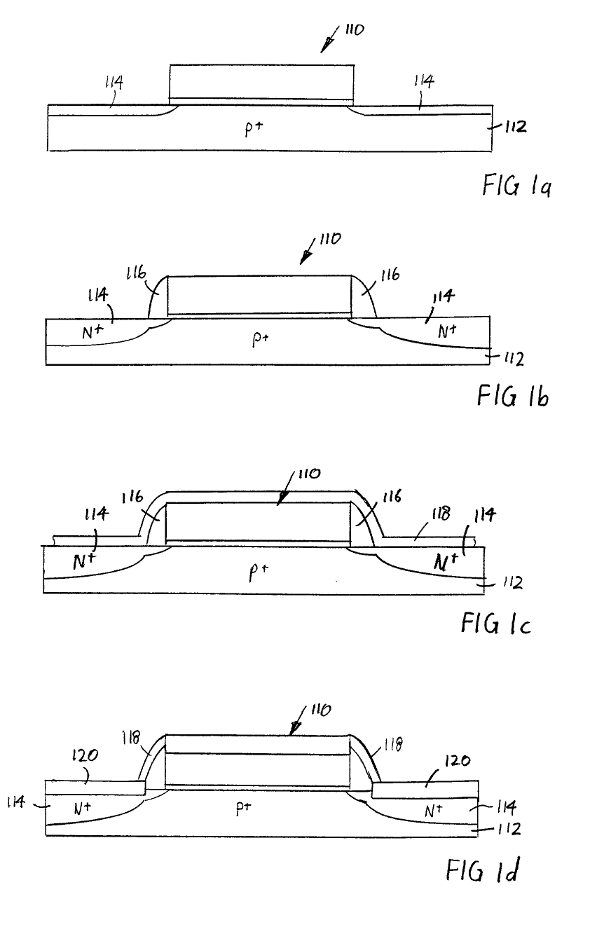

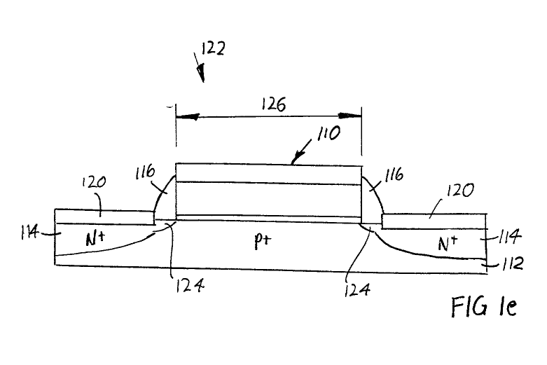

### DETAILED DESCRIPTION OF THE INVENTION

A method of forming a transistor, and the transistor are described. In the following description, for purposes of explanation, numerous specific details are set forth in order to provide a thorough understanding of the present invention. It will be evident, however, to one skilled in the art, that the present invention may be practiced without these specific details.

An alignment component is formed on a substrate of a semiconductor material which is N- or P-doped. A metal layer is deposited over the substrate and the alignment component. The metal layer is reacted with the semiconductor material of the substrate to form two silicide regions, on opposing sides of the alignment component, which extend up to the alignment component. The alignment component is then replaced with a gate which extends up to the silicide regions. A transistor results wherein inner surfaces of the silicide regions, facing one another, are in direct contact with the N- or P-doped semiconductor material of the substrate and therefore have a low series resistance between them. There is also no need for forming source and drain regions of opposite doping of the substrate which may outdiffuse and cause leaking of the transistor. By doing away with the risk of outdiffusion and leaking of the transistor, (a) a gate length of the transistor can be reduced and (b) there is a reduced need for increasing dopant concentration within the semiconductor material of the substrate which would result in a higher threshold voltage of the transistor.

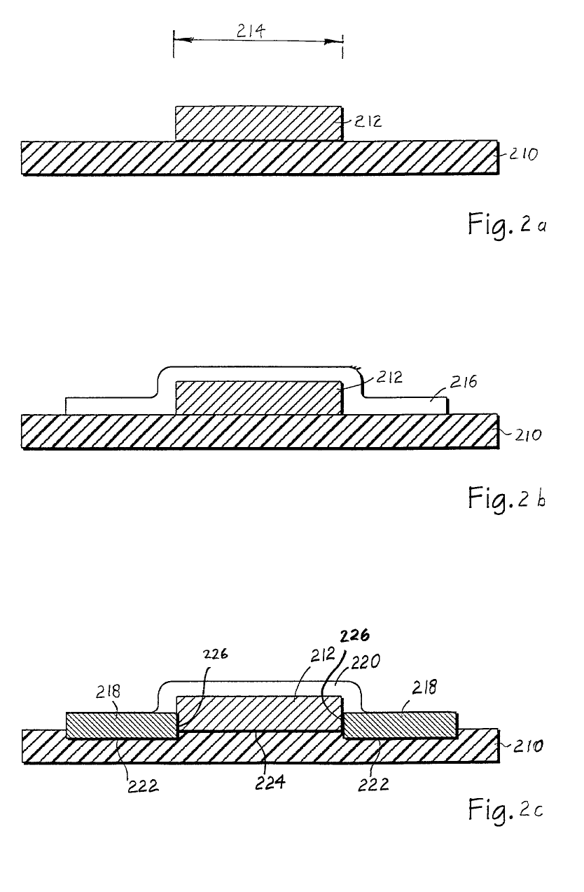

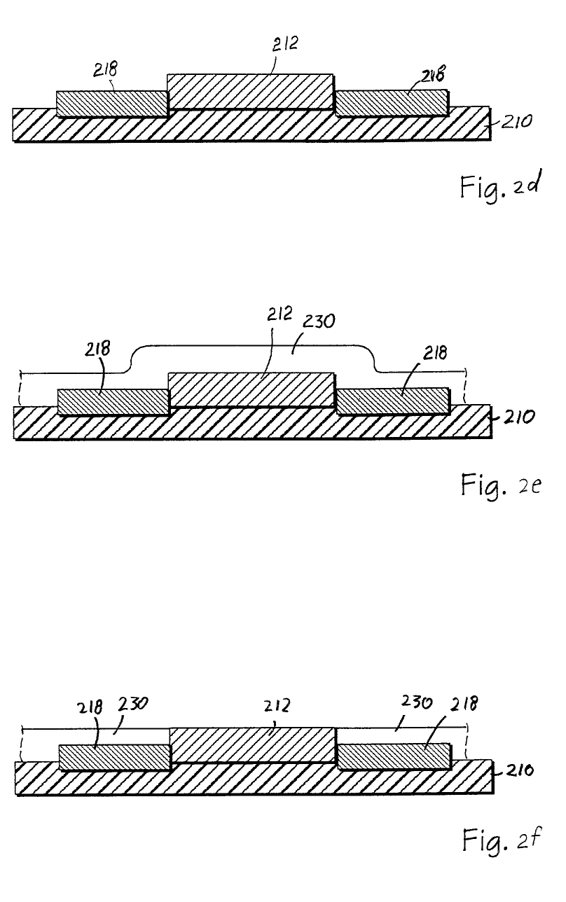

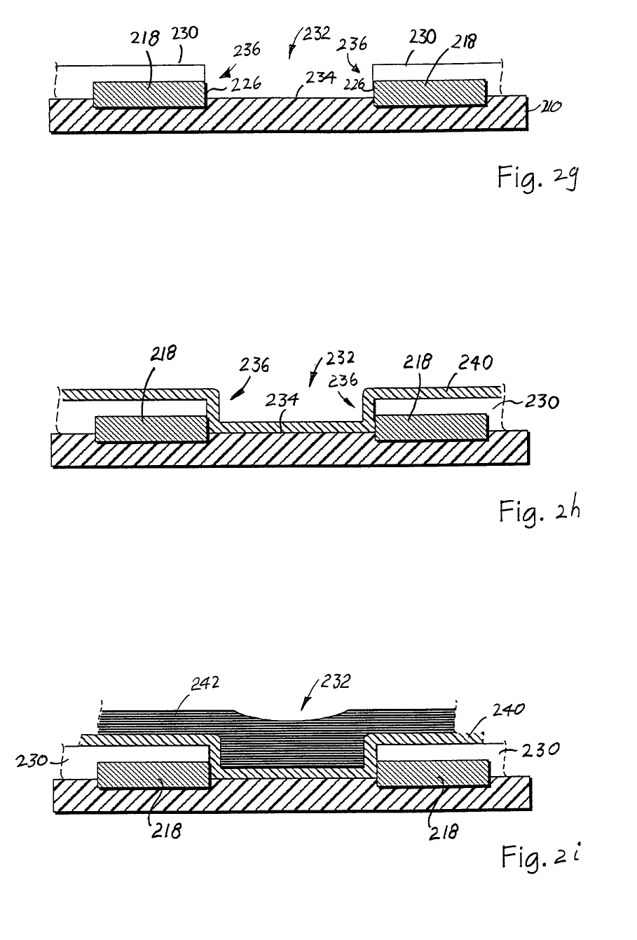

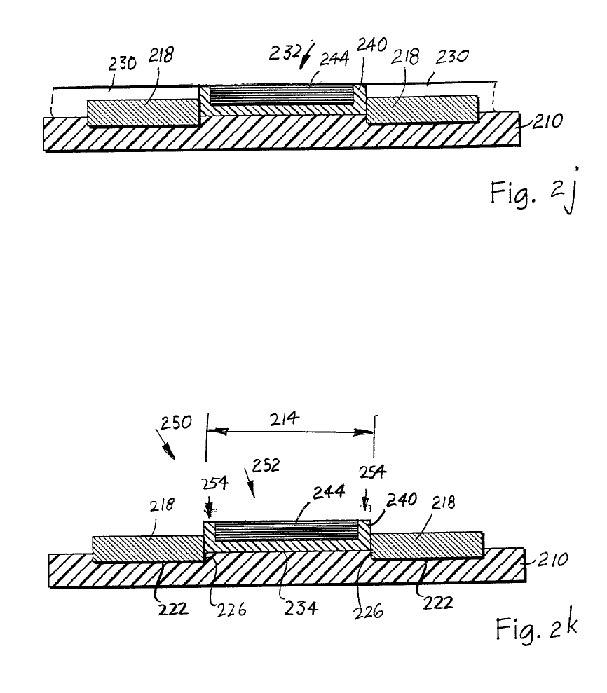

FIG. 2a of the accompanying drawings illustrates a first step in forming a transistor according to the invention. A substrate 210 of a semiconductor material such as silicon is provided. The semiconductor material is typically N or P doped. An alignment component 212 is formed on the substrate 210. The alignment component 212 may be made of a non-conductive material such as a silicon oxide or silicon nitride. The alignment component 212 may be formed according to conventional methods wherein a layer is deposited on the substrate 210, and the layer is patterned utilizing conventional photolithographic or other techniques. The alignment component may have a thickness of between 1000 Å and 2500 Å, typically in the region of about 1500 Å, and preferably has a width 214 of less than 0.10 microns although the width 214 may be less than 0.05 microns.

Next, as illustrated in FIG. 2b, a metal layer 216 is deposited onto the substrate 210 and onto the alignment component 212. The metal layer 216 may be conformally deposited. The metal layer 216 may be between 300 Å and 400 Å thick, typically in the region of about 350 Å thick. The metal layer may be made of tungsten, cobalt, titanium, or any other metal forming a silicide.

Next, as illustrated in FIG. 2c, the metal layer 216 is reacted with the semiconductor material of the substrate 210, typically by heating the metal layer 216 to a temperature in the region of about 700° C. Heating of the metal layer 216 results in the formation of two silicide regions 218 on opposing sides of the alignment component 212. The alignment component 212 may be made of a material which does not react with the metal layer 216 when the metal layer 216 is reacted with the semiconductor material of the substrate 210, so that a portion 220 of the metal layer 216 may remain unreacted over the alignment component 212. The silicide regions 218 have lower surfaces 222 which are located lower than a lower surface 224 of the alignment component 212. The silicide regions 218 also have inner surfaces 226, facing one another, an upper portion of which contacting the alignment component 212 and a lower portion of which contact the N- or P- doped semiconductor material of the substrate 210. A silicide region which is in contact with a semiconductor material of a substrate is also known as a “Schottky junction”. Although not shown in the drawings, the silicide regions 218 may also form partially below the alignment component 212. The use of a metal layer 216 of cobalt and nickel is particularly useful for diffusing into the silicon and for forming partially below the alignment component 212.

Next, as illustrated in FIG. 2d, the unreacted metal portion 220 is removed with an etchant which removes the material of the metal layer 216 selectively over the material of the alignment component 212 and the material of the silicide regions 218.

FIGS. 2e to 2k illustrate a method of replacing the alignment component 212 with a gate for the transistor.

First, as illustrated in FIG. 2e, a layer 230 is deposited over the silicide regions 218 and the alignment component 212. The layer 230 and the alignment component 212 are made of different materials. The alignment component 212 may, for example, be made of a silicon oxide and the layer 230 may be made of silicon nitride, or vice versa. Of importance is that the material of the alignment component 212 can be selectively etched over the material of the layer 230.

Next, as illustrated in FIG. 2f, the layer 230 is planarized, typically in a conventional chemical-mechanical polishing operation. Planarization is continued at least until the alignment component 212 is exposed, but without removing the layer 230 above the silicide regions 218.

Next, as illustrated in FIG. 2g, the alignment component 212 is etched away utilizing an etchant which removes the material of the alignment component 212 selectively over the material of the substrate 210, the material of the silicide regions 218, and the material of the layer 230. Removal of the alignment component 212 leaves an opening 232. The opening 232 has a lower surface 234 on the substrate 210, and side walls 236. Lower portions of the side walls 236 are defined by the upper portions of the inner surfaces 226 of the silicide regions 218 and upper portions of the side walls 236 are defined by the layer 230. The silicide regions 218 therefore extend up to the opening 232.

Next, as illustrated in FIG. 2h, a gate dielectric layer 240 is deposited. The gate dielectric layer 240 forms on the layer 230, on the side walls 236 of the opening 232, and on the lower surface 234 of the opening 232. The gate dielectric layer 240 may be made of a material such as a silicon oxide (SiO₂), which has a dielectric constant of about 4, or silicon nitride (Si₃N₄) which has a dielectric constant of between about 8 and 9. The gate dielectric layer 240 may alternatively be of a material having a higher dielectric constant (a high dielectric constant material) of at least 100. A high dielectric constant material may, for example, be strontium titanate (SrTiO₃), barium strontium titanate (BST) or a similar mixed oxide material. The gate dielectric layer 240 is supported by the side walls 236 of the opening, allowing for the gate dielectric layer to be made relatively thin typically having a thickness of less than 100 Å. The gate dielectric layer 240 is preferably less than 10 Å in thickness if it is made of silicon dioxide. In another embodiment the gate dielectric layer 240 may, alternatively, be grown in a conventional process.

FIGS. 2i to 2k now illustrate how a gate electrode is formed on the gate dielectric layer 240.

First, as illustrated in FIG. 2i, a metal layer 242 is deposited which covers the gate dielectric layer and fills the opening 232. The metal layer 242 may be a tungsten layer or a molybdenum layer in the case where the gate dielectric layer 242 is made of silicon dioxide or silicon nitride. Although a metal layer 242 is used as an example, it should be understood that a silicon or other semiconductor material may alternatively be used and later be doped to make it conductive. However, in the case where a high dielectric constant material is used as the gate dielectric layer 240, the metal layer 242 may be platinum or a conductive metal oxide such as ruthenium oxide (RuO₂) which will not, or will only minimally, react with the high dielectric constant material at a high temperature step.

Next, as illustrated in FIG. 2j, the metal layer 242 is planarized, typically in a conventional chemical-mechanical polishing operation. Planarization is continued until the layer 230 is exposed. Once planarization is completed, a portion of the metal layer 242 remains within the opening 232, forming a gate electrode 244 of metal.

Next, as illustrated in FIG. 2k, the layer 230 is removed with an etchant which removes the material of the layer 230 selectively over the material of the gate electrode 244, the material of the gate dielectric layer 240, and the material of the silicide regions 218. A metal-oxide-semiconductor (MOS) transistor 250 is so provided having a substrate 210 of semiconductor material, a gate 252 on the substrate 210, and silicide regions 218 on opposing sides of the gate 252. In an alternative method, terminal openings may be formed through the layer 230 and terminals may extend through the terminal openings and make contact with the silicide regions 218.

The gate 252 has a gate dielectric layer 240 on the substrate 210 and extending upwardly from the substrate 210 to form a surrounding spacer wall 254, and a gate electrode 244 on the gate dielectric layer 240 and within the surrounding spacer wall 254. It can be seen from the aforegoing description that the gate 252 has a gate length 214 which is determined by, and is exactly the same, as the width 214 of the alignment component 212 (see FIG. 2a).

The silicide regions 218 extend up to the gate 252. The silicide regions 218 have lower surfaces 222 located lower than a lower surface 224 of the gate 252. Inner surfaces 226 of the silicide regions 218 face one another and are in direct contact with the N- or P-doped semiconductor material of the substrate 210, thus forming Schottky junctions. Because the surrounding wall 254 may be less than 10 Å thick, the gate electrode 244 may be spaced from the silicide regions 218 by less than 10 Å.

In use, an electrical voltage is applied to the silicide regions 218. A voltage may be applied to the gate electrode 244 so as to cause current to flow between the two silicide regions 218, thereby causing “switching” of the transistor 250 according to conventional semiconductor physics. Because the silicide regions form Schottky junctions, a very low series resistance exists between the silicide regions 218, thus increasing the performance of the transistor 250.

Furthermore, because the gate dielectric layer 224, and therefore also the surrounding spacer wall 254, is very thin, the gate electrode 244 operates very close to the silicide regions 218. The surrounding spacer wall 254 is therefore not a substantial cause of an increased series resistance between the silicide regions 218, especially since the silicide regions 218 are partially formed below the gate 252. Although, as previously discussed, the surrounding spacer wall 254 is preferably less than 10 Å thick, the transistor could conceivably work with a surrounding spacer wall 254 which is less than 100 Å thick.

Furthermore, it can be seen that there is no need for the formation of source and drain regions which are oppositely doped to the remainder of the substrate 210. There is therefore no risk of outdiffusion of dopants from source and drain regions which could cause the transistor 250 to leak. The lack of doped source and drain regions which could outdiffuse has a number of advantages. Firstly, there is a reduced need for increasing the dopant concentration in the remainder of the substrate 210 which would result in a higher threshold voltage of the transistor 250. There is thus a reduced need for a high dose implant below the surface 234 (the so-called punch through implant). A dopant concentration of the substrate 210 of less than 1×10¹⁸ atoms per cubic centimeter may therefore suffice. Secondly, the gate length 214 of the transistor 250 can be reduced with less risk of leakage of the transistor 250. A shorter gate length 214, in turn, results in a faster transistor. A gate length 214 of less than 0.10 microns, or even less than 0.05 microns, is within the scope of the invention. The transistor 250 is therefore faster and has a lower threshold voltage due to the lack of doped source and drain regions.

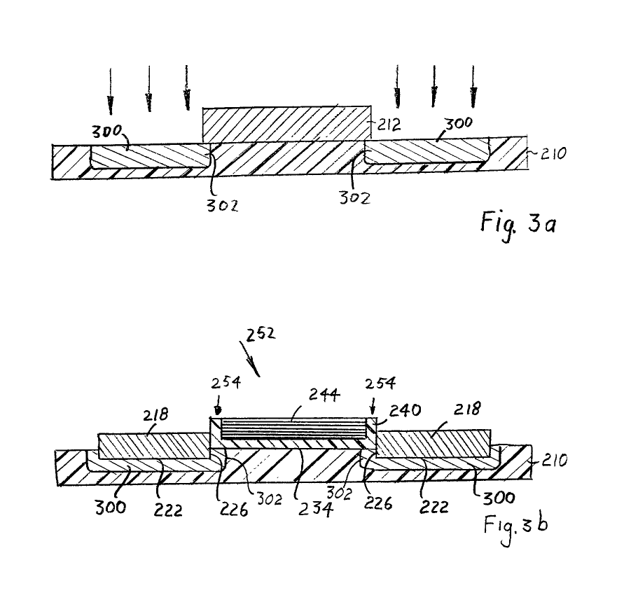

As mentioned, the gate electrode 244 may be spaced from the silicide regions 218 by a very small distance, and may therefore operate very closely to the conductive silicide regions 218. FIGS. 3a and 3b now illustrate how additional, doped regions may be formed. The doped regions are conductive and are located even closer to the gate electrode 244.

FIG. 3a is a view similar to FIG. 2a after a dopant implantation step. Dopant implantation processes are known in the art. N- or P-doped regions 300 are formed next to the alignment component 212. Each doped regions 300 diffuses in underneath the alignment component 212 so that a portion 302 of the doped region 300 is located under the alignment component 212.

When the transistor is finally formed as shown in FIG. 3b, the portion 302 of each doped region 300 is located below the gate 252 and extends from a respective silicide region 218 past the surrounding sidewall 254 up to a location below the gate electrode 244. The gate electrode 244 thus operates very close to the conductive doped regions 300. The portions 302 of the doped regions 300 need not be much wider than the thickness of the surrounding sidewall 254, and therefore do not substantially increase the series resistance between the two silicide regions 218. The portions 302 of the doped regions 300 typically extend in underneath the gate 252 by a distance of less than 20 Å.

Thus, a method of forming a transistor, and a transistor are described. While certain exemplary embodiments have been described and shown in the accompanying drawings, it is to be understood that such embodiments are merely illustrative and not restrictive of the current invention, and that this invention is not restricted to the specific constructions and arrangements shown and described, since modifications may occur to those ordinarily skilled in the art.

What is claimed:

1. A method of forming a transistor, comprising:
forming an alignment component on a substrate of a semiconductor material;
depositing a metal layer over the substrate and the alignment component;
reacting the metal layer with the semiconductor material of the substrate to form two silicide regions substantially extending up to the alignment component on opposing sides of the alignment component; and
replacing the alignment component with a conductive gate substantially extending up to the silicide regions.

2. The method of claim 1 wherein the alignment component is non-conductive.

3. The method of claim 2 wherein the alignment component is made of a material selected from the group consisting of a silicon oxide and silicon nitride.

4. The method of claim 1 wherein the alignment component is made of a material which does not react with the metal layer when the metal layer is reacted with the semiconductor material of the substrate.

5. The method of claim 1 wherein the alignment component has a thickness of between 1000 Å and 2500 Å.

6. The method of claim 1 wherein the alignment component is less than 0.10 microns wide.

7. The method of claim 1 wherein the metal layer is selected from the group consisting of a material comprising tungsten, cobalt and titanium.

8. The method of claim 1 wherein the metal layer is between 300 Å and 400 Å thick.

9. The method of claim 1 wherein the silicide regions have lower surfaces located lower than a lower surface of the alignment component, and inner surfaces, facing one another, which are in contact with the semiconductor material of the substrate.

10. The method of claim 1 wherein the alignment component is replaced with the gate according to a method comprising:
depositing a layer over the silicide regions and the alignment component;
planarizing the layer at least until the alignment component is exposed;
etching the alignment component to leave an opening in the first layer; and
disposing a gate within the opening.

11. The method of claim 10 wherein, after etching of the alignment component, the silicide regions extend substantially up to the opening.

12. The method of claim 10 wherein the alignment component and the layer are made of different materials, one being made of a silicon oxide and the other being made of silicon nitride.

13. The method of claim 1 wherein the gate is formed according to a method comprising:
depositing a gate dielectric layer; and
forming a gate electrode on the gate dielectric layer.

14. The method of claim 13 wherein the gate dielectric layer is less than 10 Å thick.

15. The method of claim 13 wherein the gate electrode is made out of a metal.

16. The method of claim 1, further comprising:
forming doped regions which extend from the silicide regions in underneath the gate.

17. The method of claim 13 wherein the gate dielectric layer has a dielectric constant of at least 100.

18. The method of claim 13 wherein the gate dielectric layer comprises a material selected from the group consisting of strontium titanate, and barium strontium titanate.

19. The method of claim 17 wherein the gate electrode comprises a material selected from the group consisting of platinum, a conductive metal oxide, and ruthenium oxide.

20. A transistor comprising:
a substrate of a semiconductor material;
a gate on the substrate, the gate having a gate dielectric layer, on the substrate, which is less than 100 Å thick, and a gate electrode on the gate dielectric layer; and
two silicide regions on opposing sides of the gate and substantially extending up to the gate.

21. The transistor of claim 20 wherein the silicide regions have lower surfaces located lower than a lower surface of the gate, and inner surfaces, facing one another, which are in contact with the semiconductor material of the substrate wherein the substrate has the same type dopant from the one silicide region to the other silicide region.

22. The transistor of claim 20 wherein the gate has a gate length of less than 0.10 microns.

23. The transistor of claim 20 wherein the gate comprises:
a spacer wall between the gate electrode and one of the silicide regions, the spacer wall being less than 100 Å thick.

24. The transistor of claim 20 wherein a single layer forms both the gate dielectric layer and the spacer wall.

25. The transistor of claim 20, further comprising:
a respective doped region which extends from a respective silicide region in underneath the gate.
